(19) United States
(12) Patent Application Publication
(10) Pub. No.: US 2022/0271094 A1
(43) Pub. Date: Aug. 25, 2022

(54) IMAGE SENSOR PIXEL

(71) Applicant: ISORG, Limoges CEDEX 3 (FR)

(72) Inventors: Camille DUPOIRON, GRENOBLE (FR); Benjamin BOUTHINON, GRENOBLE (FR)

(21) Appl. No.: 17/627,584

(22) PCT Filed: Jul. 16, 2020
(86) PCT No.: PCT/EP2020/070074

§ 371 Date: Jan. 14, 2022

(30) Foreign Application Priority Data
Jul. 19, 2019 (FR) FR19/08254

(51) Int. Cl. H01L 27/30

(52) U.S. Cl. CPC H01L 27/307; H01L 51/447

(57) ABSTRACT

A pixel includes a CMOS support and at least two organic photodetectors. A same lens is vertically in line with the organic photodetectors.

The present patent application claims the priority benefit of French patent application FR19/08254, which is herein incorporated by reference.

### FIELD

The present disclosure relates to an image sensor or electronic imager.

### BACKGROUND

Image sensors are currently used in many fields, in particular in electronic devices. Image sensors are particularly present in man-machine interface applications or in image capture applications. The fields of use of such image sensors particularly are, for example, smart phones, motors vehicles, drones, robotics, and virtual or augmented reality systems.

In certain applications, a same electronic device may have a plurality of image sensors of different types. Such a device may thus comprise, for example, a first color image sensor, a second infrared image sensor, a third image sensor enabling to estimate a distance, relative to the device, of different points of a scene or of a subject, etc.

Such a multiplicity of image sensors embarked in a same device is, by nature, little compatible with current constraints of miniaturization of such devices.

### SUMMARY

There is a need to improve existing image sensors.

An embodiment overcomes all or part of the disadvantages of known image sensors.

An embodiment provides a pixel comprising:
a CMOS support; and
at least two organic photodetectors,
where a same lens is vertically in line with said organic photodetectors.

An embodiment provides an image sensor comprising a plurality of pixels such as described.

An embodiment provides a method of manufacturing such a pixel or such an image sensor, comprising steps of:
providing a CMOS support;
forming at least two organic photodetectors per pixel;
forming a same lens vertically in line with the organic photodetectors of the or of each pixel.

According to an embodiment, at least two photodetectors, among said organic photodetectors are stacked.

According to an embodiment, at least two photodetectors, among said organic photodetectors, are coplanar.

According to an embodiment, said organic photodetectors are separated from one another by a dielectric.

According to an embodiment, each organic photodetector comprises a first electrode, separate from first electrodes of the other organic photodetectors.

According to an embodiment, each first electrode is coupled, preferably connected, to a readout circuit, each readout circuit preferably comprising three transistors formed in the CMOS support.

According to an embodiment, said organic photodetectors are capable of estimating a distance by time of flight.

According to an embodiment, the pixel or the sensor such as described is capable of operating:
in a portion of the infrared spectrum;
in structured light;
in high dynamic range imaging, HDR; and/or with a background suppression.

According to an embodiment, each pixel further comprises, under the lens, a color filter giving way to electromagnetic waves in a frequency range of the visible spectrum and in the infrared spectrum.

According to an embodiment, the sensor such as described is capable of capturing a color image.

According to an embodiment, each pixel exactly comprises:
a first organic photodetector;
a second organic photodetector; and
a third organic photodetector.

According to an embodiment, the third organic photodetector, on the one hand, and the first and second organic photodetectors, on the other hand, are stacked, said first and second organic photodetectors being coplanar.

According to an embodiment, for each pixel, the first organic photodetector and the second organic photodetector have a rectangular shape and are jointly inscribed within a square.

According to an embodiment, for each pixel:
the first organic photodetector is connected to a second electrode;
the second organic photodetector is connected to a third electrode; and
the third organic photodetector is connected to a fourth electrode.

According to an embodiment:
the first organic photodetector and the second organic photodetector comprise a first active layer formed of a same first material; and
the third organic photodetector comprises a second active layer made of a second material.

According to an embodiment, the first material is different from the second material, said first material being capable of absorbing the electromagnetic waves of part of the infrared spectrum and said second material being capable of absorbing the electromagnetic waves of the visible spectrum.

According to an embodiment:
the second electrode is common to all the first organic photodetectors of the pixels of the sensor;
the third electrode is common to all the second organic photodetectors of the sensor pixels; and
the fourth electrode is common to all the third organic photodetectors of the sensor pixels.

### BRIEF DESCRIPTION OF THE DRAWINGS

The foregoing and other features and advantages of the present invention will be discussed in detail in the following non-limiting description of specific embodiments and implementation modes in connection with the accompanying drawings, in which:

FIG. 1 is a partial simplified exploded perspective view of an embodiment of an image sensor;

FIG. 2 is a partial simplified top view of the image sensor of FIG. 1;

FIG. 3 is an electric diagram of an embodiment of the readout circuits of a pixel of the image sensor of FIGS. 1 and 2;

FIG. 4 is a timing diagram of signals of an example of operation of the image sensor having the readout circuits of FIG. 3;

FIG. 5 is a partial simplified cross-section view of a step of an implementation mode of a method of forming the image sensor of FIGS. 1 and 2;

FIG. 6 is a partial simplified cross-section view of another step of the implementation mode of the method of forming the image sensor of FIGS. 1 and 2;

FIG. 7 is a partial simplified cross-section view of still another step of the implementation mode of the method of forming the image sensor of FIGS. 1 and 2;

FIG. 8 is a partial simplified cross-section view of still another step of the implementation mode of the method of forming the image sensor of FIGS. 1 and 2;

FIG. 9 is a partial simplified cross-section view of still another step of the implementation mode of the method of forming the image sensor of FIGS. 1 and 2;

FIG. 10 is a partial simplified cross-section view of still another step of the implementation mode of the method of forming the image sensor of FIGS. 1 and 2;

FIG. 11 is a partial simplified cross-section view of still another step of the implementation mode of the method of forming the image sensor of FIGS. 1 and 2;

FIG. 12 is a partial simplified cross-section view of still another step of the implementation mode of the method of forming the image sensor of FIGS. 1 and 2;

FIG. 13 is a partial simplified cross-section view of still another step of the implementation mode of the method of forming the image sensor of FIGS. 1 and 2;

FIG. 14 is a partial simplified cross-section view of still another step of the implementation mode of the method of forming the image sensor of FIGS. 1 and 2;

FIG. 15 is a partial simplified cross-section view of still another step of the implementation mode of the method of forming the image sensor of FIGS. 1 and 2;

FIG. 16 is a partial simplified cross-section view along plane AA of the image sensor of FIGS. 1 and 2;

FIG. 17 is a partial simplified cross-section view along plane BB of the image sensor of FIGS. 1 and 2; and

FIG. 18 is a partial simplified cross-section view of another embodiment of an image sensor.

### DESCRIPTION OF THE EMBODIMENTS

Like features have been designated by like references in the various figures. In particular, the structural and/or functional elements common to the different embodiments and implementation modes may be designated with the same reference numerals and may have identical structural, dimensional, and material properties.

For clarity, only those steps and elements which are useful to the understanding of the described embodiments and implementation modes have been shown and will be detailed. In particular, what use is made of the image sensors described hereafter has not been detailed.

Unless specified otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings or to an image sensor in a normal position of use.

Unless specified otherwise, the expressions “around”, “approximately”, “substantially” and “in the order of” signify within 10%, and preferably within 5%.

In the following description, a signal which alternates between a first constant state, for example, a low state, noted “0”, and a second constant state, for example, a high state, noted “1”, is called a “binary signal”. The high and low states of different binary signals of a same electronic circuit may be different. In particular, the binary signals may correspond to voltages or to currents which may not be perfectly constant in the high or low state.

In the following description, unless specified otherwise, it is considered that the terms “insulating” and “conductive” respectively mean “electrically insulating” and “electrically conductive”.

The transmittance of a layer to a radiation corresponds to the ratio of the intensity of the radiation coming out of the layer to the intensity of the radiation entering the layer, the rays of the incoming radiation being perpendicular to the layer. In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%.

In the following description, “visible light” designates an electromagnetic radiation having a wavelength in the range from 400 nm to 700 nm and “infrared radiation” designates an electromagnetic radiation having a wavelength in the range from 700 nm to 1 mm. In infrared radiation, near infrared radiation having a wavelength in the range from 700 nm to 1.7 μm can in particular be distinguished.

A pixel of an image corresponds to the unit element of the image captured by an image sensor. When the optoelectronic device is a color image sensor, it generally comprises, for each image pixel of the color image to be acquired, at least three components which each acquire a light radiation substantially in a single color, that is, in a wavelength range having a width smaller than 130 nm (for example, red, green, and blue). Each component may particularly comprise at least one photodetector.

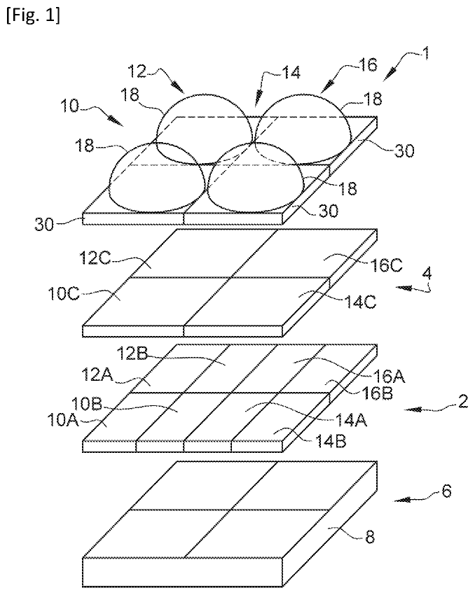

FIG. 1 is a partial simplified exploded perspective view of an embodiment of an image sensor 1.

Image sensor 1 comprises a plurality of pixels, for example, several millions, or even several tens of millions of pixels. However, for simplification, only four pixels 10, 12, 14, and 16 of image sensor 1 have been shown in FIG. 1, it being understood that, in practice, image sensor 1 may comprise more pixels. These pixels of image sensor 1 may be distributed in rows and in columns.

Image sensor 1 comprises a first array 2 of photon sensors, also called photodetectors, and a second array 4 of photodetectors. In image sensor 1, each pixel 10, 12, 14, 16 comprises three photodetectors, each belonging to one or the other of the two arrays 2, 4 of photodetectors.

In FIG. 1, each pixel 10, 12, 14, 16 of image sensor 1 more particularly comprises:
a first photodetector, belonging to first array 2 of photodetectors and bearing suffix “A”;
a second photodetector, belonging to first array 2 of photodetectors and bearing suffix “B”; and
a third photodetector, belonging to first array 4 of photodetectors and bearing suffix “C”.

Thus, in FIG. 1:
pixel 10 comprises a first photodetector 10A, a second photodetector 10B, and a third photodetector 10C;
pixel 12 comprises a first photodetector 12A, a second photodetector 12B, and a third photodetector 12C;
pixel 14 comprises a first photodetector 14A, a second photodetector 14B, and a third photodetector 14C; and
pixel 16 comprises a first photodetector 16A, a second photodetector 16B, and a third photodetector 16C.

Photodetectors 10A, 10B, 10C, 12A, 12B, 12C, 14A, 14B, 14C, 16A, 16B, and 16C may correspond to organic photodiodes (OPD) or to organic photoresistors. In the following description, it is considered that the photodetectors of the pixels of image sensor 1 correspond to organic photodiodes.

In image sensor 1, each pixel 10, 12, 14, 16 further comprises a lens 18, also called microlens 18 due to its dimensions, and a color filter 30 located under microlens 18. In the simplified representation of FIG. 1, color filters 30 are interposed between the second array 4 of photodetectors and microlenses 18.

First array 2 of photodetectors and second array 4 of photodetectors are stacked, so that third photodetectors 10C, 12C, 14C, 16C are stacked both to the first photodetectors 10A, 12A, 14A, 16A and to the second photodetectors 10B, 12B, 14B, 16B. In image sensor 1, first photodetectors 10A, 12A, 14A, 16A and second photodetectors 10B, 12B, 14B, 16B are coplanar.

The first array 2 of first photodetectors 10A, 12A, 14A, 16A and of second photodetectors 10B, 12B, 14B, 16B as well as the second array 4 of third photodetectors 10C, 12C, 14C, 16C are both associated with a third array 6 of readout circuits, thus measuring the signals captured by the photodetectors of arrays 2 and 4. Readout circuit means an assembly of transistors for reading out, addressing, and controlling a photodetector. More generally, the readout circuits associated with the different photodetectors of a same pixel jointly form a readout circuit of the considered pixel.

According to this embodiment, the third array 6 of readout circuits of image sensor 1 is formed in a CMOS support 8. CMOS support 8 is for example, a piece of a silicon wafer on top and inside of which integrated circuits (not shown) have been formed in CMOS (Complementary Metal Oxide Semiconductor) technology. The integrated circuits thus form, still according to this embodiment, the third array 6 of readout circuits. In the simplified representation of FIG. 1, the first array 2 of photodetectors covers the third array 6 of readout circuits, so that the two arrays 2, 6 are stacked.

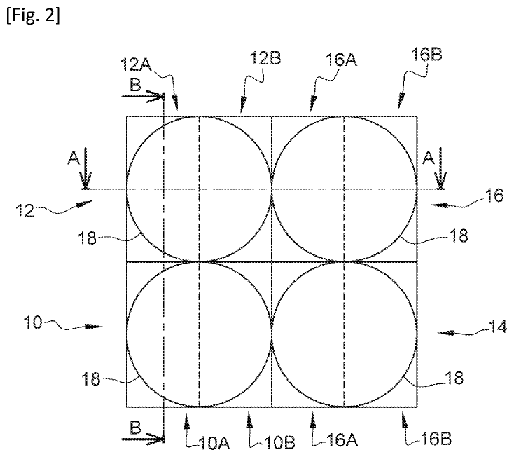

FIG. 2 is a partial simplified top view of the image sensor 1 of FIG. 1. In this top view, only microlenses 18, first photodetectors 10A, 12A, 14A, and 16A, and the second photodetectors 10B, 12B, 14B, and 16B of pixels 10, 12, 14, and 16 of image sensor 1 have been shown.

In image sensor 1, in top view in FIG. 2, pixels 10, 12, 14, and 16 have a substantially square shape, preferably a square shape. All the pixels of image sensor 1 preferably have identical dimensions, to within manufacturing dispersions.

The square formed by each pixel 10, 12, 14, 16 of image sensor 1, in top view in FIG. 2, has a side length approximately in the range from 0.8 μm to 10 μm, preferably in the range from approximately 0.8 μm and 5 μm, more preferably still in the range from 0.8 μm to 3 μm.

The first photodetector and the second photodetector belonging to a same pixel, for example, the first photodetector 10A and the second photodetector 10B of pixel 10, both have a rectangular shape. The photodetectors have substantially the same dimensions and are jointly inscribed within the square formed by the pixel to which they belong, pixel 10 in the present example. The rectangle formed by each photodetector of each pixel of image sensor 1 has a length substantially equal to the side length of the square formed by each pixel and a width substantially equal to half the side length of the square formed by each pixel. A space is however formed between the first and the second photodetector of each pixel, so that their respective lower electrodes are separate.

In image sensor 1, each microlens 18 has, in top view in FIG. 2, a diameter substantially equal, preferably equal to the side length of the square jointly formed by the first and second photodetectors that it covers. In the present embodiment, each pixel comprises a single microlens 18. Each microlens 18 of image sensor 1 is preferably centered with respect to the square formed by the photodetectors to which it belongs.

As a variation, each microlens 18 may be replaced with another type of micrometer-range optical element, particularly a micrometer-range Fresnel lens, a micrometer-range index gradient lens, or a micrometer-range diffraction grating. Microlenses 18 are converging lenses, each having a focal distance f in the range from 1 μm to 100 μm, preferably from 1 μm to 10 μm. According to a preferred embodiment, all microlenses 18 are substantially identical, to within manufacturing dispersions.

Microlenses 18 may be made of silica, of poly(methyl) methacrylate (PMMA), of positive resist, of polyethylene terephthalate (PET), of polyethylene naphthalate (PEN), of cyclo-olefin polymer (COP), of polydimethylsiloxane (PDMS)/silicone, or of epoxy resin. Microlenses 18 may be formed by flowing of resist blocks. Microlenses 18 may further be formed by molding on a layer of PET, PEN, COP, PDMS/silicone or epoxy resin.

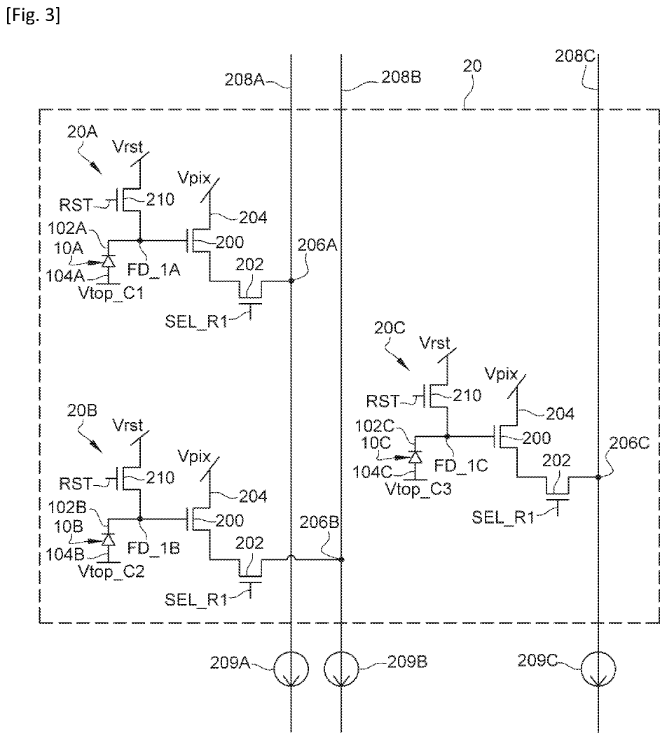

FIG. 3 is an electric diagram of an embodiment of readout circuits of pixel 10 of the image sensor 1 of FIGS. 1 and 2. In FIG. 3, only the readout circuits associated with the photodetectors of a single pixel of image sensor 1 are considered, it being understood that the other photodetectors of the other pixels of this image sensor 1 may have similar readout circuits.

It is considered, still in this example, that each photodetector is associated with its own readout circuit, enabling to drive it independently from the other photodetectors. Thus, in FIG. 3:
the first photodetector 10A of pixel 10 is associated with a first readout circuit 20A;
the second photodetector 10B of pixel 10 is associated with a second readout circuit 20B; and
the third photodetector 10C of pixel 10 is associated with a third readout circuit 20C. The three readout circuits 20A, 20B, 20C jointly form a readout circuit 20 of pixel 10.

Each readout circuit 20A, 20B, 20C comprises, in this example, three MOS transistors. Such a circuit is currently designated, with its photodetector, by the expression “3T sensor”. In particular, in the example of FIG. 3:
first readout circuit 20A, associated with first photodetector 10A, comprises a follower-assembled MOS transistor 200, in series with a MOS selection transistor 202, between two terminals 204 and 206A;
second readout circuit 20B, associated with second photodetector 10B, comprises a follower-assembled MOS transistor 200, in series with a MOS selection transistor 202, between two terminals 204 and 206B; and
third readout circuit 20C, associated with third photodetector 10C, comprises a follower-assembled MOS transistor 200, in series with a MOS selection transistor 202, between two terminals 204 and 206C.

Each terminal 204 is coupled to a source of a high reference potential, noted Vpix, in the case where the transistors of the readout circuits are N-channel MOS transistors. Each terminal 204 is coupled to a source of a low reference potential, for example, the ground, in the case where the transistors of the readout circuits are P-channel MOS transistors.

Terminal 206A is coupled to a first conductive track 208A. First conductive track 208A may be coupled to all the first photodetectors of the pixels of a same column. The first conductive track 208A is preferably coupled to all the first photodetectors of image sensor 1.

Similarly, terminal 206B, respectively 206C, is coupled to a second conductive track 208B, respectively to a third track 208C. Second track 208B, respectively third track 208C, may be coupled to all the second photodetectors, respectively to all the third photodetectors, of the pixels of a same column. Track 208B, respectively 208C, is preferably coupled to all the second photodetectors, respectively to all the third photodetectors, of image sensor 1. First conductive track 208A, second conductive track 208B, and third conductive track 208C are preferably distinct from one another.

In the embodiment of FIG. 3:
first conductive track 208A is coupled, preferably connected, to a first current source 209A;
second conductive track 208B is coupled, preferably connected, to a second current source 209B; and
third conductive track 208C is coupled, preferably connected, to a third current source 209C.

Current sources 209A, 209B, and 209C do not form part of the readout circuit 20 of pixel 10 of image sensor 1. In other words, the current sources 209A, 209B, and 209C of image sensor 1 are external to the pixels and readout circuits.

The gate of the transistors 202 of the readout circuits of pixel 10 is intended to receive a signal, noted SEL_R1, of selection of pixel 10. It is assumed that the gate of the transistors 202 of the readout circuit of another pixel of image sensor 1, for example, the readout circuit of pixel 12, is intended to receive another signal, noted SEL_R2, of selection of pixel 12.

In the example of FIG. 3:
the gate of the transistor 200 associated with the first photodetector 10A of pixel 10 is coupled to a node FD_1A;
the gate of the transistor 200 associated with the second photodetector 10B of pixel 10 is coupled to a node FD_1B; and
the gate of the transistor 200 associated with the third photodetector 10C of pixel 10 is coupled to a node FD_1C.

Each node FD_1A, FD_1B, FD_1C is coupled, by a reset MOS transistor 210, to a terminal of application of a reset potential Vrst, which potential may be identical to potential Vpix. The gate of transistor 210 is intended to receive a signal RST for controlling the resetting of the photodetector, particularly enabling to reset node FD_1A, FD_1B, or FD_1C substantially to potential Vrst.

In the example of FIG. 3:
node FD_1A is connected to a cathode electrode 102A of the first photodetector 10A of pixel 10;
node FD_1B is connected to a cathode electrode 102B of the second photodetector 10B of pixel 10; and
node FD_1C is connected to a cathode electrode 102C of the third photodetector 10C of pixel 10.

Still in the example of FIG. 3:
an anode electrode 104A of the first photodetector 10A of pixel 10 is coupled to a source of a reference potential Vtop_C1;
an anode electrode 104B of the second photodetector 10B of pixel 10 is coupled to a source of a reference potential Vtop_C2; and
an anode electrode 104C of the third photodetector 10C of pixel 10 is coupled to a source of a reference potential Vtop_C3.

In image sensor 1, potential Vtop_C1 is for example applied to a first upper electrode common to all the first photodetectors of image sensor 1. Similarly, potential Vtop_C2, respectively Vtop_C3, is applied to a second upper electrode common to all the second photodetectors, respectively to a third electrode common to all the third photodetectors, of image sensor 1.

In the rest of the disclosure, the following notations are arbitrarily used:
VFD_1A for the voltage present at node FD_1A;
VFD_1B for the voltage present at node FD_1B;
VSEL_R1 for the voltage applied to the gate of the transistors 202 of the readout circuit 20 of pixel 10, that is, the voltage applied to the gate of the transistor 202 of the first photodetector 10A, of second photodetector 10B, and of third photodetector 10C; and
VSEL_R2 for the voltage applied to the gate of the transistors 202 of the readout circuit of pixel 12.

It is considered in the rest of the disclosure that the application of voltage VSEL_R1, respectively VSEL_R2, is controlled by the binary signal noted SEL_R1, respectively SEL_R2.

Other types of sensors, for example, so-called “4T” sensors, are known. The use of organic photodetectors advantageously enables to spare a transistor and to use a 3T sensor.

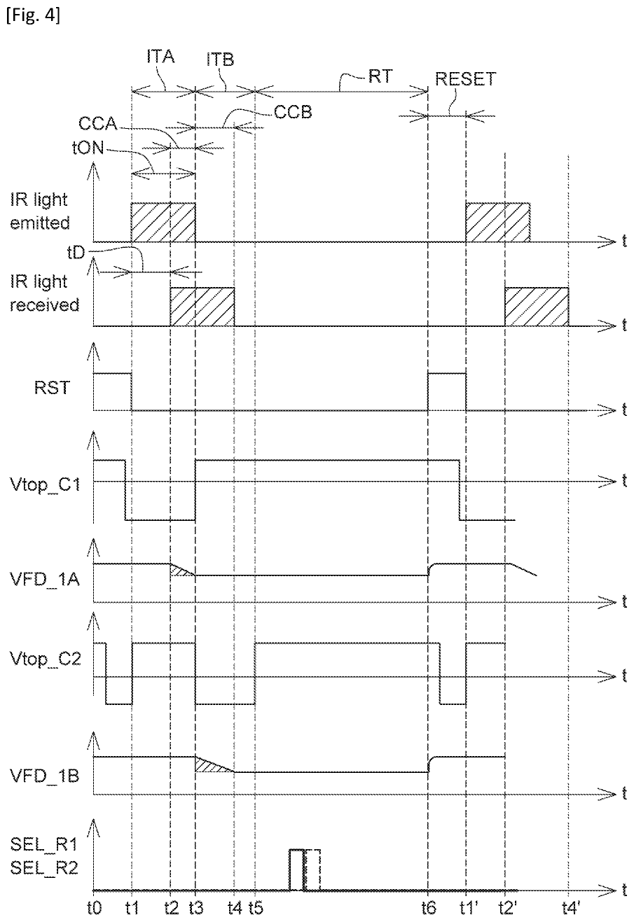

FIG. 4 is a timing diagram of signals of an example of operation of image sensor 1 having the readout circuit of FIG. 3.

The timing diagram of FIG. 4 more particularly corresponds to an example of operation of image sensor 1 in “time-of-flight” (ToF) mode. In this operating mode, the pixels of image sensor 1 are used to estimate a distance separating them from a subject (object, scene, face, etc.) placed or located opposite image sensor 1. To estimate this distance, it is started by emitting a light pulse towards the subject with an associated emitter system which is not described in the present text. Such a light pulse is generally obtained by briefly illuminating the subject with a radiation originating from a source, for example, a near infrared radiation originating from a light-emitting diode. The light pulse is then at least partially reflected by the subject, and then captured by image sensor 1. A time taken by the light pulse to make a return travel between the source and the subject is then calculated or measured. Image sensor 1 being advantageously located close to the source, this time corresponds to approximately twice the time taken by the light pulse to travel the distance separating the subject from image sensor 1.

The timing diagram of FIG. 4 illustrates an example of variation of binary signals RST and SEL_R1 as well as of the potentials Vtop_C1, Vtop_C2, VFD_1A, and VFD_1B of the first photodetector 10A and of the second photodetectors 10B of pixel 10. FIG. 4 also shows, in dotted lines, the binary signal SEL_R2 of pixel 12. The timing diagram of FIG. 4 has been established considering that the MOS transistors of the readout circuit 20 of pixel 10 are N-channel transistors. For simplification, the driving of the third photodetectors of the pixels of image sensor 1 is not detailed in FIG. 4.

At a time t0, signal SEL_R1 is in the low state, so that the transistors 202 of pixel 10 are off. A reset phase is then initiated. For this purpose, signal RST is maintained in the high state so that the reset transistors 210 of pixel 10 are on. The charges accumulated in photodiodes 10A and 10B are then discharged towards the source of potential Vrst.

Potential Vtop_C1 is, still at time t0, in a high level. The high level corresponds to a biasing of the first photodetector 10A under a voltage greater than a voltage resulting from the application of a potential called “built-in potential”. The built-in potential is equivalent to a difference between a work function of the anode and a work function of the cathode. When potential Vtop_C1 is in the high level, the first photodetector 10A integrates no charges.

Before a time t1 subsequent to time t0, potential Vtop_C1 is set to a low level. This low level corresponds to a biasing of the first photodetector 10A under a negative voltage, that is, smaller than 0 V. This thus enables to first photodetector 10A to integrate photogenerated charges. What has been previously described in relation with the biasing of first photodetector 10A by potential Vtop_C1 transposes to the explanation of the operation of the biasing of the second photodetector 10B by potential Vtop_C2.

At time t1, it is started to emit a first infrared light pulse (IR light emitted) towards a scene comprising one or a plurality of objects, the distance of which is desired to be measured, which enables to acquire a depth map of the scene. The first infrared light pulse has a duration noted tON. At time t1, signal RST is set to the low state, so that the reset transistors 210 of pixel 10 are off, and potential Vtop_C2 is set to a high level.

Potential Vtop_C1 being at the low level, at time t1, a first integration phase, noted ITA, is started in the first photodetector 10A of pixel 10 of image sensor 1. The integration phase of a pixel designates the phase during which the pixel collects charges under the effect of an incident radiation.

At a time t2, subsequent to time t1 and separated from time t1 by a time period noted tD, a second infrared light pulse originating from the reflection of the first infrared light pulse by an object of the scene or by a point of an object having its distance to pixel 10 desired to be measured, starts being received (IR light received). Time period tD thus is a function of the distance of the object to sensor 1. A first charge collection phase, noted CCA is then started, in first photodetector 10A. The first charge collection phase corresponds to a period during which charges are generated proportionally to the intensity of the incident light, that is, proportionally to the light intensity of the second pulse, in photodetector 10A. The first charge collection phase causes a decrease in the level of potential VFD_1A at node FD_1A of readout circuit 20A.

At a time t3, in the present example subsequent to time t2 and separated from time t1 by time period tON, the first infrared light pulse stops being emitted. Potential Vtop_C1 is simultaneously set to the high level, thus marking the end of the first integration phase, and thus of the first charge collection phase.

At the same time, potential Vtop_C2 is set to a low level. A second integration phase, noted ITB, is then started at time t3 in the second photodetector 10B of pixel 10 of image sensor 1. Given that the second photodetector 10B receives light originating from the second light pulse, a second charge collection phase, noted CCB, is started, still at time t3. The second charge collection phase causes a decrease in the level of potential VFD_1B at node FD_1B of readout circuit 20B.

At a time t4, subsequent to time t3 and separated from time t2 by a time period substantially equal to tON, the second light pulse stops being captured by the second photodetector 10B of pixel 10. The second charge collection phase then ends at time t4.

At a time t5, subsequent to time t4, potential Vtop_C2 is set to the high level. This thus marks the end of the second integration phase.

Between time t5 and a time t6, subsequent to time t5, a readout phase, noted RT, is carried out during which the quantity of charges collected by the photodiodes of the pixels of image sensor 1 is measured. For this purpose, the pixels rows of image sensor 1 are for example sequentially read. In the example of FIG. 4, signals SEL_R1 and SEL_R2 are successively set to the high state to alternately read pixels 10 and 12 of image sensor 1.

From time t6 and until a time t1′, subsequent to time t6, a new reset phase (RESET) is initiated. Signal RST is set to the high state so that the reset transistors 210 of pixel 10 are turned on. The charges accumulated in photodiodes 10A and 10B are then discharged towards the source of potential Vrst.

Time period tD, which separates the beginning of the first emitted light pulse from the beginning of the second received light pulse is calculated by means of the following formula:

$$tD = \frac{tON \times Δ VFD\_ 1 B}{Δ VFD\_ 1 A + Δ VFD\_ 1 B} \qquad [ Math 1 ]$$

In the above formula, the quantity noted ΔVFD_1A corresponds to a drop of potential VFD_1A during the integration phase of first photodetector 10A. Similarly, the quantity noted ΔVFD_1B corresponds to a drop of potential VFD_1B during the integration phase of second photodetector 10B.

At time t1′, a new distance estimation is initiated by the emission of a second light pulse. The new distance estimation comprises times t2′ and t4′ similar to times t2 and t4, respectively.

The operation of image sensor 1 has been illustrated hereabove in relation with an example of operation in time-of-flight mode, where the first and second photodetectors of a same pixel are driven in desynchronized fashion. An advantage of image sensor 1 is that it may also operate in other modes, particularly modes where the first and second photodetectors of a same pixel are driven in synchronized fashion. Image sensor 1 may for example be driven in global shutter mode, that is, image sensor 1 may also implement an image acquisition method where beginnings and ends of the integration phases of the first and second photodetectors are simultaneous.

An advantage of image sensor 1 thus is to be able to operate alternately according to different modes. Image sensor 1 may for example operate alternately in time of flight mode and in global shutter imaging mode.

According to an implementation mode, the readout circuits of the first and second photodetectors of image sensor 1 are alternately driven in other operating modes, for example, mode where image sensor 1 is capable of operating:
in a portion of the infrared spectrum;
in structured light;
in high dynamic range imaging (HDR), for example ascertaining that, for each pixel, the integration time of one of the first photodetector is greater than that of the second photodetector; and/or
with a background suppression.

Image sensor 1 may thus be used to performed different types of images with no loss of resolution, since the different imaging modes capable of being implemented by image sensor 1 use a same number of pixels. The use of image sensor 1, capable of integrating a plurality of functionalities in a same pixel array and readout circuits, particularly enables to respond to the current constraints of miniaturization of electronic devices, for example, smart phone design and manufacturing constraints.

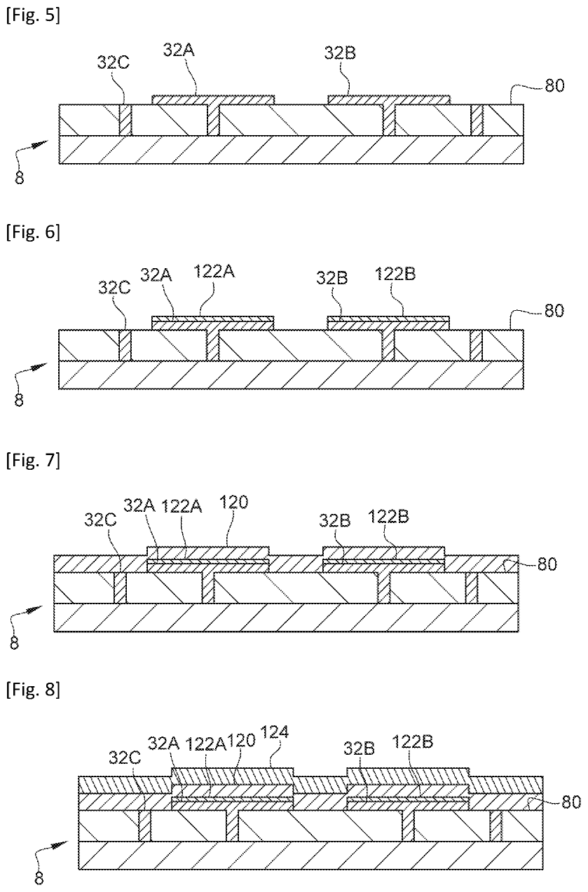

FIGS. 5 to 15 hereafter illustrate successive steps of another implementation mode of a method of forming the image sensor 1 of FIGS. 1 and 2. For simplification, what is discussed hereafter in relation with FIGS. 5 to 15 illustrates the forming of a portion of a pixel of image sensor 1, for example, the pixel 12 of image sensor 1. However, it should be understood that this method may be extended to the forming of any number of photodetectors and of pixels of an image sensor similar to image sensor 1.

According to this embodiment, the first photodetector 12A and the second photodetector 12B of pixel 12 are first formed. The third photodetector 12C of pixel 12 is then formed. The transposition of this implementation mode to the forming of all the pixels of image sensor 1 would then amount to first forming the first array 2 of first and second photodetectors, and then the second array 4 of third photodetectors.

FIG. 5 is a partial simplified cross-section view of a step of an implementation mode of a method of forming the image sensor 1 of FIGS. 1 and 2.

According to this embodiment, it is started by providing CMOS support 8 particularly comprising the readout circuits (not shown) of pixel 12. CMOS support 8 further comprises, at its upper surface 80, contacting elements 32A and 32B as well as a second contacting element 32C. First contacting elements 32A and 32B have, in cross-section view in FIG. 5, a “T”-shape, where:
a horizontal portion extends on upper surface 80 of CMOS support 8; and
a vertical portion extends downwards from the upper surface 80 of CMOS support 8 to contact lower metallization levels (not shown) of CMOS support 8 coupled or connected to the readout circuits (not shown).

First contacting elements 32A and 32B are for example formed from conductive tracks formed on the upper surface of CMOS support 8 (horizontal portions of first contacting elements 32A and 32B) and from conductive vias (vertical portions of contacting elements 32A and 32B) contacting the conductive tracks. Second contacting element 32C is for example formed from a conductive via flush with the upper surface 80 of CMOS support 8. As a variant, second contacting element 32C is also “T”-shaped. Second contacting element 32C may have dimensions smaller than those of first contacting elements 32A and 32B. The dimensions of the second contacting element 32C are then adjusted to avoid disturbing the layout of the first contacting elements 32A and 32B while providing a maximum connection surface area.

The conductive tracks and the conductive vias may be made of a metallic material, for example, silver (Ag), aluminum (Al), gold (Au), copper (Cu), nickel (Ni), titanium (Ti), and chromium (Cr), or of titanium nitride (TiN). The conductive tracks and the conductive vias may have a monolayer or multilayer structure. In the case where the conductive tracks have a multilayer structure, the conductive tracks may be formed by a stack of conductive layers separated by insulating layers. The vias then cross the insulating layers. The conductive layers may be made of a metallic material from the above list and the insulating layers may be made of silicon nitride (SiN) or of silicon oxide (SiO₂).

During this same step, CMOS support 8 is cleaned to remove possible impurities present at its surface 80. The cleaning is for example performed by plasma. The cleaning thus provides a satisfactory cleanness of CMOS support 8 before performing a series of successive depositions, detailed in relation with the following drawings.

In the rest of the disclosure, the implementation mode of the method described in relation with FIGS. 6 to 15 exclusively comprises performing operations above the upper surface 80 of CMOS support 8. The CMOS supports 8 of FIGS. 6 to 15 thus preferably is identical to the CMOS support 8 such as discussed in relation with FIG. 5 all along the process. For simplification, CMOS support 8 will not be detailed again in the following drawings.

FIG. 6 is a partial simplified cross-section view of another step of the implementation mode of the method of forming the image sensor 1 of FIGS. 1 and 2 from the structure such as described in relation with FIG. 5.

During this step, a deposition, at the surface of the first contacting elements 32A and 32B, of an electron injection material, is performed. A material selectively bonding to the surface of contacting elements 32A and 32B to form a self-assembled monolayer is preferably deposited. This deposition thus preferably or only covers the free upper surfaces of first contacting elements 32A and 32B. One thus forms, as illustrated in FIG. 6:
a lower electrode 122A of the first organic photodetector 12A of pixel 12; and
a lower electrode 122B of the second organic photodetector 12B of pixel 12.

As a variant, a full plate deposition of an electron injection material having a sufficiently low lateral conductivity to avoid creating conduction paths between two neighboring contacting elements.

Lower electrodes 122A and 122B form electron injection layers (EIL) and photodetectors 12A and 12B, respectively. Lower electrodes 122A and 122B preferably form the cathodes of the photodetectors 12A and 12B of image sensor 1. Lower electrodes 122A and 122B are preferably formed by spin coating or by dip coating.

The material forming lower electrodes 122A and 122B is selected from the group comprising:
a metal or a metallic alloy, for example, silver (Ag), aluminum (Al), lead (Pb), palladium (Pd), gold (Au), copper (Cu), nickel (Ni), tungsten (W), molybdenum (Mo), titanium (Ti) or chromium (Cr), or an alloy of magnesium and silver (MgAg);
a transparent conductive oxide (TCO), particularly indium tin oxide (ITO), aluminum zinc oxide (AZO), gallium zinc oxide (GZO), an ITO/Ag/ITO multilayer, an ITO/Mo/ITO multilayer, a AZO/Ag/AZO multilayer, or a ZnO/Ag/ZnO multilayer;
a polyethyleneimine (PEI) polymer or a polyethyleneimine ethoxylated (PEIE), propoxylated, and/or butoxylated polymer;
carbon, silver, and/or copper nanowires;
graphene; and
a mixture of at least two of these materials.

Lower electrodes 122A and 122B may have a monolayer or multilayer structure.

FIG. 7 is a partial simplified cross-section view of still another step of the embodiment of the method of forming the image sensor 1 of FIGS. 1 and 2 from the structure such as described in relation with FIG. 6.

During this step, a non-selective deposition of a first layer 120 is performed on the upper surface side 80 of CMOS support 8. The deposition is called “full plate” deposition since it covers the entire upper surface 80 of CMOS support 8 as well as the free surfaces of contacting elements 32A and 32B, of second contacting elements 32C, and of lower electrodes 122A and 122C. According to this embodiment, first layer 120 is intended to form active layers of the first photodetector 12A and of the second photodetector 12B of pixel 12. The deposition of first layer 120 is preferably performed by spin coating.

First layer 120 may comprise small molecules, oligomers, or polymers. These may be organic or inorganic materials, particularly comprising quantum dots. First layer 120 may comprise an ambipolar semiconductor material, or a mixture of an N-type semiconductor material and of a P-type semiconductor material, for example in the form of stacked layers or of an intimate mixture at a nanometer scale to form a bulk heterojunction. The thickness of first layer 120 may be in the range from 50 nm to 2 μm, for example, in the order of 300 nm.

Examples of P-type semiconductor polymers capable of forming layer 120 are:
poly(3-hexylthiophene) (P3HT);
poly[N-9′-heptadecanyl-2,7-carbazole-alt-5,5-(4,7-di-2-thienyl-2′,1′,3′-benzothiadiazole] (PCDTBT);
poly[(4,8-bis-(2-ethylhexyloxy)-benzo[1,2-b;4,5-b′]dithiophene)-2,6-diyl-alt-(4-(2-ethylhexanoyl)-thieno[3,4-b]thiophene))-2,6-diyl] (PBDTTT-C);
poly[2-methoxy-5-(2-ethyl-hexyloxy)-1,4-phenylene-vinylene] (MEH-PPV); and
poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials capable of forming layer 120 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

FIG. 8 is a partial simplified cross-section view of still another step of the embodiment of the method of forming the image sensor 1 of FIGS. 1 and 2 from the structure such as described in relation with FIG. 7.

During this step, a non-selective deposition (full plate deposition) of a second layer 124 is performed on the upper surface side 80 of CMOS support 8. The deposition covers the entire upper surface of first layer 120. According to this implementation mode, second layer 124 is intended to form upper electrodes of the first photodetector 12A and of the second photodetector 12B of pixel 12. The deposition of second layer 124 is preferably performed by spin coating.

Second layer 124 is at least partially transparent to the light radiation that it receives. Second layer 124 may be made of a transparent conductive material, for example, of transparent conductive oxide (TCO), of carbon nanotubes, of graphene, of a conductive polymer, of a metal, or of a mixture or an alloy of at least two of these compounds. Second layer 124 may have a monolayer or multilayer structure.

Examples of TCOs capable of forming second layer 124 are indium tin oxide (ITO), aluminum zinc oxide (AZO), and gallium zinc oxide (GZO), titanium nitride (TiN), molybdenum oxide (MoO₃), and tungsten oxide (WO₃). An example of a conductive polymer capable of forming second layer 124 is the polymer known as PEDOT:PSS, which is a mixture of poly(3,4)-ethylenedioxythiophene and of sodium poly(styrene sulfonate), and polyaniline, also called PAni. Examples of metals capable of forming second layer 124 are silver, aluminum, gold, copper, nickel, titanium, and chromium. An example of a multilayer structure capable of forming second layer 124 is a multilayer AZO and silver structure of AZO/Ag/AZO type.

The thickness of second layer 124 may be in the range from 10 nm to 5 μm, for example, in the order of 60 nm. In the case where second layer 124 is metallic, the thickness of second layer 124 is smaller than or equal to 20 nm, preferably smaller than or equal to 10 nm.

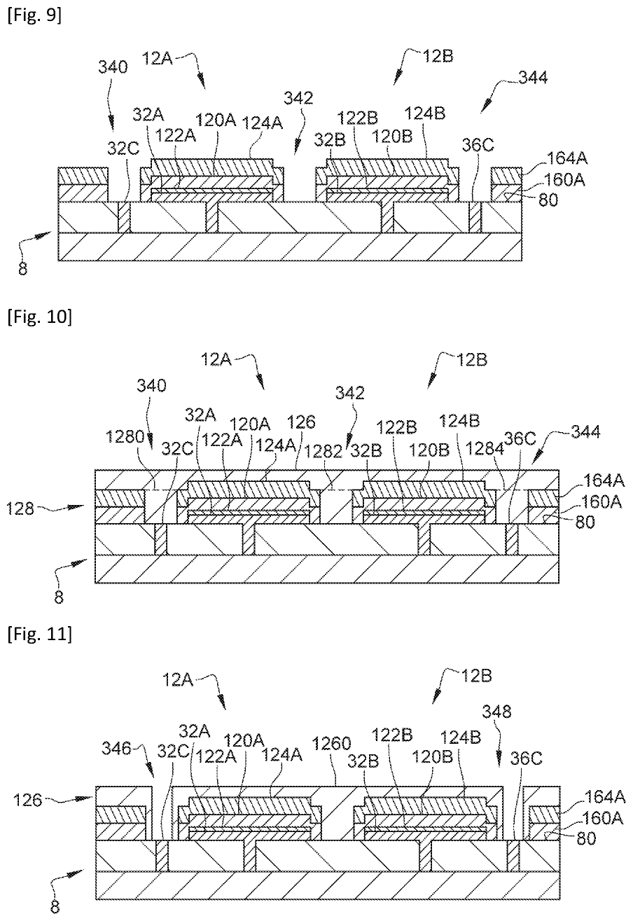

FIG. 9 is a partial simplified cross-section view of still another step of the embodiment of the method of forming the image sensor 1 of FIGS. 1 and 2 from the structure such as described in relation with FIG. 8.

During this step, a second vertical opening 340, a second vertical opening 342, and a third vertical opening 344 are formed through second layer 124 and through first layer 120, all the way to the upper surface 80 of CMOS support 8. In the example of FIG. 9:
first vertical opening 340 and second vertical opening 342 are located on either side of first contacting element 32A (respectively to the left and to the right of first contacting element 32A); and
second vertical opening 342 and third vertical opening 344 are located on either side of first contacting element 32B (respectively to the left and to the right of second contacting element 32B).

The three vertical openings 340, 342, and 344 particularly aim at separating photodetectors belonging to a same row of image sensor 1. First vertical opening 340 further enables to expose the upper surface of second contacting element 32C. Similarly, third opening 344 enables to expose the upper surface of a third contacting element 36C similar to the second contacting element 32C. Openings 340, 342, and 344 are for example formed due to successive steps of deposition of photoresist, of exposure to ultraviolet light through a mask (photolithography), and of physical etching, for example, a reactive ion etching (RIE).

One thus obtains, as illustrated in FIG. 9:
an active layer 120A of the first photodetector 12A of pixel 12, which totally covers the free surfaces of the first contacting element 32A and lower electrode 122A;
an active layer 120B of the second photodetector 12B of pixel 12, which totally covers the free surfaces of the second contacting element 32B and lower electrode 122B;
an upper electrode 124A of the first photodetector 12A of pixel 12, covering active area 120A; and
an upper electrode 124B of the second photodetector 12B of pixel 12, covering active area 120B.

Thus, still in the example of FIG. 9:
opening 340 is interposed between, on the one hand, the active layer 120A and the upper electrode 124A of the first photodetector 12A of pixel 12 and, on the other hand, an active layer and an upper electrode of a second photodetector belonging to a neighboring pixel (not shown);
opening 342 is interposed between, on the one hand, the active layer 120A and the upper electrode 124A of the first photodetector 12A of pixel 12 and, on the other hand, the active layer 120B and the upper electrode 124B of the second photodetector 12B of pixel 12; and
opening 344 is interposed between, on the one hand, the active layer 120B and the upper electrode 124B of the first photodetector 12B of pixel 12 and, on the other hand, an active layer 160A and an upper electrode 164A of the first photodetector 16A of pixel 16 (partially shown in FIG. 9).

Upper electrodes 124A and 124B form hole injection layers (HIL) of photodetectors 12A and 12B, respectively. Upper electrodes 124A and 124B for example form the anodes of the photodetectors 12A and 12B of image sensor 1. Each photodetector is thus formed, as illustrated in FIG. 9, of an active layer interposed (or “sandwiched”) between a lower electrode and an upper electrode.

FIG. 10 is a partial simplified cross-section view of still another step of the embodiment of the method of forming the image sensor 1 of FIGS. 1 and 2 from the structure such as described in relation with FIG. 9.

During this step, a third layer 126 is deposited over the entire structure on the side of upper surface 80 of CMOS support 8. Third layer 126 is preferably a so-called “planarization” layer enabling to obtain a structure having a planar upper surface before the encapsulation of the photodetectors.

In FIG. 10, third layer 126 fills first opening 340, second opening 342, and third opening 344. Further, third layer 126 integrally covers the stacks respectively formed by first photodetector 12A and by second photodetector 12B. In other words, first photodetector 12A and second photodetector 12B are embedded in third planarization layer 126.

Third planarization layer 126 may be made of a dielectric material based on polymers. Third planarization layer 126 may as a variant contain a mixture of silicon nitride (SiN) and of silicon oxide (SiO₂), this mixture being obtained by sputtering, by physical vapor deposition (PVD), or by plasma-enhanced chemical vapor deposition (PECVD).

Third planarization layer 126 may also be made of a fluorinated polymer, particularly the fluorinated polymer commercialized under trade name “Cytop” by Bellex, of polyvinylpyrrolidone (PVP), of polymethyl methacrylate (PMMA), of polystyrene (PS), of parylene, of polyimide (PI), of acrylonitrile butadiene styrene (ABS), of polydimethylsiloxane (PDMS), of a photolithography resin, of epoxy resin, of acrylate resin, or of a mixture of at least two of these compounds.

As a variant, the deposition of third layer 126 may be preceded by a deposition of a fourth so-called filling or insulation layer 128. Filling layer 128, only portions 1280, 1282, and 1284 of which (in dotted lines) are shown in FIG. 10, then preferably has a thickness substantially equal to that of the stack jointly formed by first layer 120 and by second layer 124. Portions 1280, 1282, and 1284 respectively fill first opening 340, second opening 342, and third opening 344. In other words, filling layer 128 covers in this case, by its portions 1280, 1282, and 1284, free areas of the upper surface 80 of CMOS support 8 and is thus substantially flush with the upper surface of second layer 124.

In image sensor 1, fourth filling layer 128 aims at electrically insulating each photodetector from the neighboring photodetectors. According to an embodiment, the material of filling layer 128 at least partially reflects the light received by image sensor 1 to optically isolate the photodetectors from one another. Filling layer 128 is then called “black resin”.

Filling layer 128 may be an inorganic material, for example, made of silicon oxide (SiO₂) or of silicon nitride (SiN).

Filling layer 128 may be made of a fluorinated polymer, particularly the fluorinated polymer commercialized under trade name “Cytop” by Bellex, of polyvinylpyrrolidone (PVP), of polymethyl methacrylate (PMMA), of polystyrene (PS), of parylene, of polyimide (PI), of acrylonitrile butadiene styrene (ABS), of polydimethylsiloxane (PDMS), of a photolithography resin, of epoxy resin, of acrylate resin, or of a mixture of at least two of these compounds.

Filling layer 128 may also be made of aluminum oxide (Al₂O₃). The aluminum oxide may possibly be deposited by atomic layer deposition (ALD). The maximum thickness of filling layer 128 may be in the range from 50 nm to 2 μm, for example, in the order of 400 nm.

It is assumed, in the rest of the description, that the variant comprising depositing, before third planarization layer 126, fourth filling layer 128 is not retained in the implementation mode of the method. It is thus considered that only the third planarization layer has been deposited, planarization layer 126 filling openings 340, 342, and 344 and integrally covering the stacks formed by photodetectors 12A and 12B. However, the adaptation of the following steps to a case where the deposition of third planarization layer 126 is preceded by the deposition of fourth filling layer 128 is within the abilities of those skilled in the art based on the indications provided hereafter.

FIG. 11 is a partial simplified cross-section view of still another step of the embodiment of the method of forming the image sensor 1 of FIGS. 1 and 2 from the structure such as described in relation with FIG. 10.

During this step, a fourth opening 346 and a fifth opening 348 are formed in third planarization layer 126. Fourth opening 346 and fifth opening 348 are respectively located vertically in line with second contacting element 32C and with third contacting element 36C.

Fourth opening 346 and fifth opening 348 may be formed by photolithography. As a variant, fourth opening 346 and fifth opening 348 may be formed by a lift-off technique comprising performing successive operations:
deposition of a sacrificial resin layer, located at the level of second contacting element 32C and of third contacting element 36C, to form resin pads;
deposition of third planarization layer 126; and
separation of the resin pads to suppress portions of third planarization layer 126 located vertically in line with second contacting element 32C and with third contacting element 36C.

According to this variant, the deposition of third planarization layer 126 is preferably performed directionally. The deposition of this layer 126 is for example performed by plasma-enhanced chemical vapor deposition (PECVD).

Fourth opening 346 and fifth opening 348 aim at respectively exposing or disengaging the upper surfaces of second contacting element 32C and of third contacting element 36C. Fourth opening 346 and fifth opening 348 preferably have horizontal dimensions greater than those of second contacting element 32C and of third contacting element 36C.

Fourth opening 346 and fifth opening 348 are located on either side of the first photodetector 12A and of the second photodetector 12B of the pixel 12 of image sensor 1. In FIG. 11, a portion 1260 of third planarization layer 126 thus covers the stacks formed by first photodetector 12A and by second photodetector 12B.

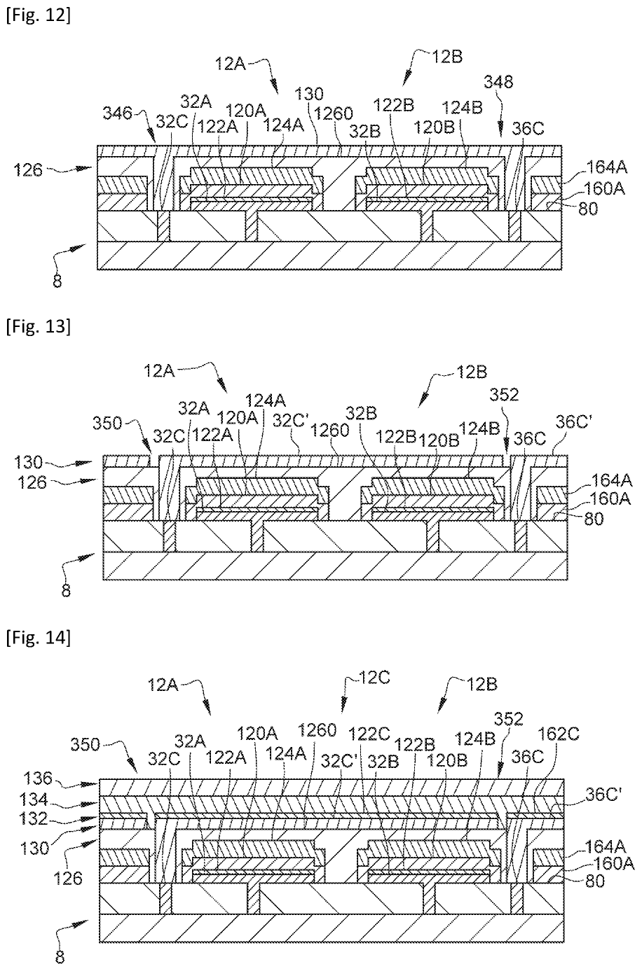

FIG. 12 is a partial simplified cross-section view of still another step of the embodiment of the method of forming the image sensor 1 of FIGS. 1 and 2 from the structure such as described in relation with FIG. 11.

During this step, a fifth layer 130 is deposited over the entire structure on the side of upper surface 80 of CMOS support 8. In FIG. 12, fifth layer 130 totally fills fourth opening 346 and fifth opening 348. Further, fifth layer 130 totally covers the free upper surface of the portions of third planarization layer 126, in particular portion 1260 of third layer 126.

According to this embodiment, fifth layer 130 is particularly intended to subsequently form contacting elements of the third photodetectors of image sensor 1. Fifth layer 130 may be made of the same materials as those discussed in relation with FIG. 8 for second layer 124. Fifth layer 130 is preferably made of metal. In the case where fifth layer 130 is metallic, the thickness of fifth layer 130 is smaller than or equal to 20 nm, preferably smaller than or equal to 10 nm. Fifth layer 130 is preferably transparent to the radiations captured by the future first photodetector 12A and by the future second photodetector 12B. Fifth layer 130 may be made of transparent conductive oxide, for example, indium tin oxide (ITO).

FIG. 13 is a partial simplified cross-section view of still another step of the embodiment of the method of forming the image sensor 1 of FIGS. 1 and 2 from the structure such as described in relation with FIG. 12.

During this step, a sixth opening 350 and a seventh opening 352 are formed in fifth layer 130 down to the upper surface of the portions of third layer 126. In FIG. 13, sixth opening 350 and seventh opening 352 delimit a fourth contacting element 32C′ formed in fifth layer 130. Fourth contacting element 32C′ has, in FIG. 13, an “L” shape. Fourth contacting element 32C′ touches the upper surface of second contacting element 32C and partially covers the upper surface of portion 1260 of third layer 126.

Fourth contacting element 32C′ aims at continuing second contacting element 32C at the surface of portion 1260 of third layer 126. Second contacting element 32C and fourth contacting element 32C′ thus jointly form a same contacting element of the third photodetector 12C of pixel 12 of image sensor 1.

Similarly, a fifth contacting element 36C′, formed in fifth layer 130, continues third contacting element 36C. Third contacting element 36C and fifth contacting element 36C′ thus jointly form a same contacting element of the third photodetector 16C of pixel 16 of image sensor 1. In FIG. 13, fourth contacting element 32C′ is separated from the fifth contacting element 36C′ by seventh opening 352.

Sixth opening 350 and seventh opening 352 are preferably formed by photolithography. Fourth contacting element 32C′ and fifth contacting element 36C′ are preferably obtained by reactive ion etching (RIE) or by etching by means of a solvent.

As a variant, sacrificial pads are deposited before performing the deposition of fifth layer 130 as discussed in relation with FIG. 12. The pads are possibly arranged at the locations of sixth opening 350 and of seventh opening 352. The sacrificial pads are then removed by lift-off to form openings 350 and 352 during the step discussed in relation with FIG. 13.

FIG. 14 is a partial simplified cross-section view of still another step of the embodiment of the method of forming the image sensor 1 of FIGS. 1 and 2 from the structure such as described in relation with FIG. 13.

During this step, a deposition, at the surface of fifth layer 130, of a sixth layer 132 is performed. A material selectively bonding to the surface of contacting elements 32C′ and 36C′ is preferably deposited to form a self-assembled monolayer. One thus forms, as illustrated in FIG. 14:
lower electrode 122C, covering the upper surface of fourth contacting element 32C′, of the third photodetector 12C of pixel 12; and
lower electrode 162C, covering the upper surface of fifth contacting element 36C′, of the third photodetector 16C of pixel 16.

Lower electrodes 122C and 162C respectively form electron injection layers (EIL) of the third photodetectors 12C and 16C. Lower electrodes 122C and 162C respectively form, for example, the cathodes of the third photodetectors 12C and 16C of image sensor 1.

The lower electrodes 122C and 162C of the third photodetectors 12C and 16C may be made of the same materials as the lower electrodes 122A and 122B of first photodetector 12A and of second photodetector 12B. Lower electrodes 122C and 162C may further have a monolayer or multilayer structure.

During this step, a non-selective deposition (full plate deposition) of a seventh layer 134 is also performed on the side of upper surface 80 of CMOS support 8. Seventh layer 134 thus fills sixth opening 350 and seventh opening 352 and totally covers the lower electrode 122C of the third photodetector 12C of pixel 12 and the lower electrode 162C of the third photodetector 16C of pixel 16. According to this embodiment, seventh layer 134 is intended to form active layers of the third photodetectors of the pixels of image sensor 1.

According to a preferred implementation mode, the composition of seventh layer 134 is different from that of first layer 120. First layer 120 for example has an absorption wavelength of approximately 940 nm while seventh layer 134 for example has absorption wavelength centered on the visible wavelength range.

During this step, a non-selective deposition (full plate deposition) of an eighth layer 136 is performed on the side of upper surface 80 of CMOS support 8. The deposition thus covers the entire upper surface of seventh layer 134. According to this implementation mode, eighth layer 136 is intended to form upper electrodes of the third photodetectors 12C and 16C of pixels 12 and 16, respectively.

Eighth layer 136 is at least partially transparent to the light radiation that it receives. Eighth layer 136 may be made of a material similar to that discussed in relation with FIG. 8 for second layer 124.

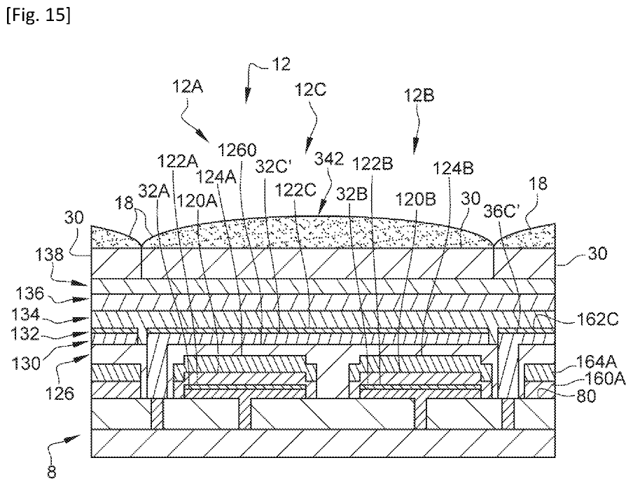

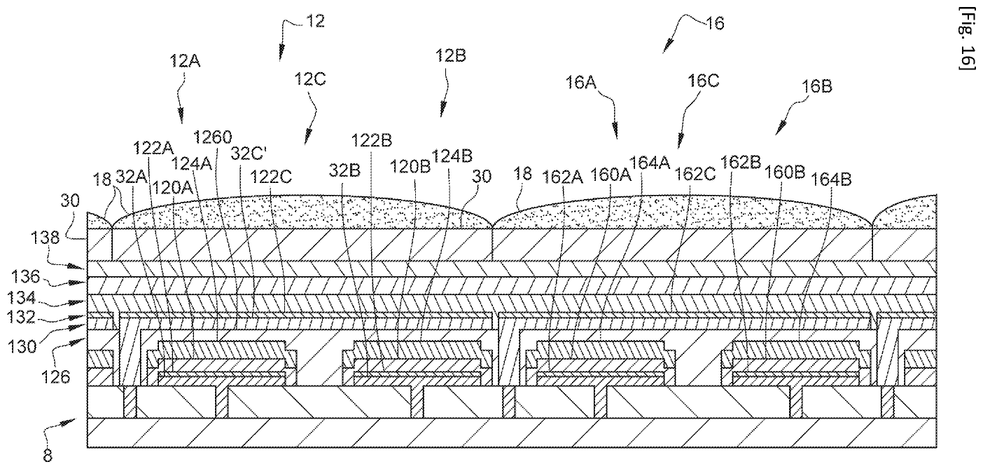

FIG. 15 is a partial simplified cross-section view of still another step of the embodiment of the method of forming the image sensor 1 of FIGS. 1 and 2 from the structure such as described in relation with FIG. 14.

During this step, a ninth layer 138, called passivation layer 138, is deposited all over the structure on the side of upper surface 80 of CMOS support 8. Ninth layer 138 aims at encapsulating the organic photodetectors of image sensor 1. Ninth layer 138 thus enables to avoid the degradation, due to an exposure to water or to the humidity contained, for example, in the ambient air, of the organic materials forming the photodetectors of image sensor 1. In the example of FIG. 15, ninth layer 138 covers the entire free upper surface of eighth layer 136.

Passivation layer 138 may be made of alumina (Al₂O₃) obtained by an atomic layer deposition method (ALD), of silicon nitride (Si₃N₄) or of silicon nitride (SiO₂) obtained by physical vapor deposition (PVD), of silicon nitride obtained by plasma-enhanced chemical vapor deposition (PECVD). Passivation layer 138 may alternately be made of PET, of PEN, of COP, or of CPI.

According to an embodiment, passivation layer 138 enables to further improve the surface condition of the structure before the forming of color filters 30 and of microlenses 18.

During this step, a color filter 30 is formed vertically in line with the location of each pixel. More particularly, in FIG. 15, a same color filter 30 is formed vertically in line with the three photodetectors 12A, 12B, and 12C of pixel 12. In other words, each pixel of image sensor 1 has a single color filter 30 common to the first, second, and third photodetectors of the considered pixel.

During this step, the microlens 18 of pixel 12 is formed vertically in line with photodetectors 12A, 12B, and 12C. In the example of FIG. 15, microlens 18 is substantially centered with respect to the opening 342 separating first photodetector 12A from second photodetector 12B. The pixel 12 of image sensor 1 is thus obtained.

A microlens 18 is located vertically in line with each color filter 30 of image sensor 1, so that image sensor 1 comprises as many color filters 30 as microlenses 18. Color filters 30 and microlenses 18 preferably have identical lateral dimensions so that each microlens 18 of a given pixel totally covers the color filter with which it is associated, without for all this covering the color filters 30 belonging to the adjacent pixels.

Color filters 30 are preferably filters centered on a color of the visible spectrum (red, green, or blue) to provide a good selectivity of the wavelength range received by third photodetector 12C. Color filters 30 however give way to the radiation which has not been absorbed by third photodetector 12C but absorbed by first photodetector 12A and by second photodetector 12B, for example, the near infrared radiation around 940 nm.

FIG. 16 is a partial simplified cross-section view along plane AA (FIG. 2) of the image sensor 1 of FIGS. 1 and 2. Cross-section plane AA corresponds to a cross-section plane parallel to a pixel row of image sensor 1.

In FIG. 16, only the pixels 12 and 16 of image sensor 1 have been shown. Pixels 12 and 16 belong to a same row of pixels of image sensor 1. In the example of FIG. 16, the first photodetectors 12A, 16A and the second photodetectors 12B, 16B of pixels 12 and 16, respectively, are separated from one another. However, still in the example of FIG. 16, the third photodetectors 12C, 16C of pixels 12 and 16, respectively, share a same active layer 134 and a same upper electrode 136.

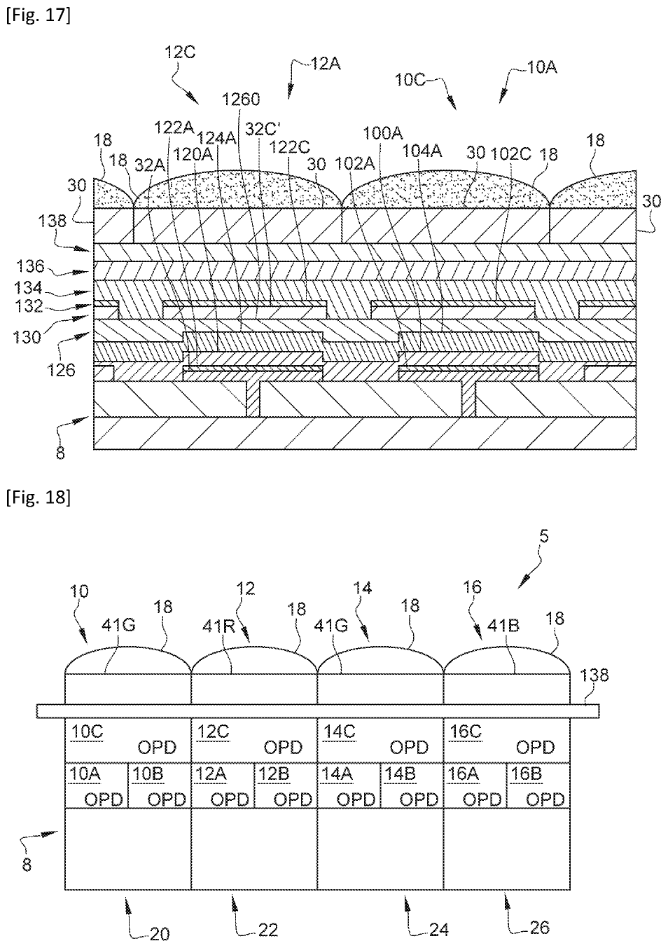

FIG. 17 is a partial simplified cross-section view along plane BB (FIG. 2) of the image sensor 1 of FIGS. 1 and 2. Cross-section plane BB corresponds to a cross-section plane parallel to a pixel column of image sensor 1.

In FIG. 17, only the first photodetectors 10A, 12A, and the third photodetectors 10C, 12C of pixels 10 and 12, respectively, are shown. In the example of FIG. 17:
the lower electrode 102A of the first photodetector 10A of pixel 10 is separated from the lower electrode 122A of the first photodetector 12A of pixel 12;
the lower electrode 102C of the third photodetector 10C of pixel 10 is separated from the lower electrode 122C of the third photodetector 12C of pixel 12;
the active layer 100A of the first photodetector 10A of pixel 10 and the active layer 120A of the first photodetector 12A of pixel 12 are formed by a same continuous deposition;
the upper electrode 104A of the first photodetector 10A of pixel 10 and the upper electrode 124A of the first photodetector 12A of pixel 12 are formed by another same continuous deposition;
the active layer of the third photodetector 10C of pixel 10 and the active layer of the third photodetector 12C of pixel 12 are formed by seventh layer 134; and
the upper electrode of the third photodetector 10C of pixel 10 and the upper electrode of the third photodetector 12C of pixel 12 are formed by eighth layer 136.

In other words, all the first photodetectors of the pixels belonging to a same pixel column of image sensor 1 have a common active layer and a common upper electrode. The upper electrode thus enables to address all the first photodetectors of the pixels of a same column while the lower electrode enables to address each first photodetector individually.

Similarly, all the second photodetectors of the pixels belonging to a same pixel column of image sensor 1 have another common active layer, separate from the common active layer of the first photodetectors of these same pixels, and another common upper electrode, separate from the common upper electrode of the first photodetectors of these same pixels. This other common upper electrode thus enables to address all the second photodetectors of the pixels of a same column while the lower electrode enables to individually address each second photodetector.

All the third photodetectors of the pixels of image sensor 1 have still another common active layer, separate from the common active layers of the first and second photodetectors of these same pixels, and still another common upper electrode, separate from the common upper electrodes of the first and second photodetectors of these same pixels. The upper electrode common to the third photodetectors thus enables to address the third photodetectors of all the pixels of image sensor 1 while the lower electrode enables to address each third photodetector individually.

FIG. 18 is a partial simplified cross-section view of another embodiment of an image sensor 5.

The image sensor 5 shown in FIG. 18 is similar to the image sensor 1 discussed in relation with FIGS. 1 and 2. Image sensor 5 differs from image sensor 1 mainly in that:
the pixels 10, 12, 14, and 16 of image sensor 5 are arranged along a same row or a same column of image sensor 5 (while the pixels 10, 12, 14, and 16 of image sensor 1 (FIG. 1) are distributed on two different rows and two different columns of image sensor 1); and
the color filters 30 of the pixels 10, 12, 14, and 16 of image sensor 1 (FIG. 1) are replaced, in image sensor 5, with color filters 41R, 41G, and 41B located between microlenses 18 and passivation layer 138. In other words, the four monochromatic pixels 10, 12, 14, and 16 arranged in a square in FIG. 1 are here placed side by side in FIG. 18.

More particularly, according to this embodiment, image sensor 5 comprises:
a first green filter 41G, interposed between the microlens 18 of pixel 10 and passivation layer 138;
a red filter 41R, interposed between the microlens 18 of pixel 12 and passivation layer 138;
a second green filter 41G, interposed between the microlens 18 of pixel 14 and passivation layer 138; and
a blue filter 41B, interposed between the microlens 18 of pixel 16 and passivation layer 138.

Still according to this embodiment, the color filters 41R, 41G, and 41B of image sensor 5 give way to electromagnetic waves in frequency ranges different from the visible spectrum and give way to the electromagnetic waves of the infrared spectrum. Color filters 41R, 41G, and 41B may correspond to colored resin blocks. Each color filter 41R, 41G, and 41B is capable of giving way to the infrared radiation, for example, at a wavelength between 700 nm and 1 mm and, for at least some of the color filters, of giving way to a wavelength range of visible light.

For each pixel of a color image to be acquired, image sensor 5 may comprise:
at least one pixel (for example, pixel 16) having its color filter 41B capable of giving way to infrared radiation and blue light, for example, in the wavelength range from 430 nm to 490 nm;
at least one pixel (for example, pixels 10 and 14) having its color filter 41G capable of giving way to infrared radiation and blue light, for example, in the wavelength range from 510 nm to 570 nm; and
at least one pixel (for example, pixel 12) having its color filter 41R capable of giving way to infrared radiation and red light, for example, in the wavelength range from 600 nm to 720 nm.

Similarly to the image sensor 1 discussed in relation with FIGS. 1 and 2, each pixel 10, 12, 14, 16 of image sensor 5 has a first and a second photodetector, the first and second photodetectors being capable of estimating a distance by time of flight, and a third photodetector capable of capturing an image. Each pixel thus comprises three photodetectors, each very schematically shown in FIG. 18 by blocks (OPD).

Similarly to image sensor 1, in image sensor 5:
pixel 10 comprises first photodetector 10A, second photodetector 10B, and third photodetector 10C;
pixel 12 comprises first photodetector 12A, second photodetector 12B, and third photodetector 12C;
pixel 14 comprises first photodetector 14A, second photodetector 14B, and third photodetector 14C; and
pixel 16 comprises first photodetector 16A, second photodetector 16B, and third photodetector 16C.

In image sensor 5, the first and second photodetectors of each pixel 10, 12, 14, and 16 are coplanar. The third photodetectors of each pixel 10, 12, 14, and 16 are coplanar and stacked on the first and second photodetectors. The first, second, and third photodetectors of pixels 10, 12, 14, and 16 are respectively associated with a readout circuit 20, 22, 24, 26. The readout circuits are formed on top of and inside of CMOS support 8. Image sensor 5 is thus capable, for example, of alternately performing time-of-flight distance estimates and color image captures.

According to an embodiment, the active layers of the first and second photodetectors of the pixels of image sensor 5 are made of a material different from that forming the active layers of the third photodetectors. According to this other embodiment:
the material forming the active layers of the first and second photodetectors is capable of absorbing the electromagnetic waves of a portion of the infrared spectrum, preferably near infrared; and
the material forming the active layers of the third photodetectors is capable of absorbing the electromagnetic waves of the visible spectrum, while giving way to the electromagnetic waves of the infrared spectrum. Active layer 134, combined with a color filter 41R, 41G, or 41B, thus enables to filter the visible light which is not captured by the photodetectors used for the time-of-flight distance estimation.

Image sensor 5 can then be used to alternately or simultaneously obtain:
time-of-flight distance estimates due to the first and second photodetectors by driving them, for example, as discussed in relation with FIG. 4; and
color images due to the third photodetectors by driving the third photodetectors, for example, in synchronized fashion.

An advantage of this preferred embodiment is that image sensor 5 is then capable of overlaying, on a color image, information resulting from the time-of-flight distance estimation. An implementation mode of the operation of image sensor 5 for example enabling to generate a color image of a subject and to include therein, for each pixel of the color image, information representative of the distance separating image sensor 5 from the area of the subject represented by the considered pixel. In other words, image sensor 5 may form a three-dimensional image of a surface of an object, of a face, of a scene, etc.

Various embodiments and variants have been described. It will be understood by those skilled in the art that certain features of these various embodiments and variations may be combined and other variations will occur to those skilled in the art.

Finally, the practical implementation of the described embodiments and variations is within the abilities of those skilled in the art based on the functional indications given hereabove. In particular, the adaptation of the driving of the readout circuits of image sensors 1 to 5 to other operating modes, for example, for the forming of infrared images with or without added light, the forming of images with a background suppression and the forming of high-dynamic range images (simultaneous HDR) is within the abilities of those skilled in the art based on the above indications.

1. A pixel comprising:
a CMOS support; and
at least first and second organic photodetectors,
wherein a same lens is vertically in line with said organic photodetectors.

2. An image sensor comprising a plurality of pixels, each of the pixels comprising:
a CMOS support; and
at least first and second organic photodetectors,
wherein a same lens is vertically in line with said organic photodetectors.

3. A method of manufacturing the pixel according to claim 1, comprising steps of:
providing a CMOS support;
forming at least two organic photodetectors; and
forming a same lens vertically in line with the organic photodetectors of the pixel.

4. The pixel according to claim 1, wherein at least two photodetectors among said organic photodetectors are stacked.

5. The pixel according to claim 1, wherein at least two photodetectors among said organic photodetectors are coplanar.

6. The pixel according to claim 1, wherein said organic photodetectors are separated from one another by a dielectric.

7. The pixel according to claim 1, wherein each organic photodetector comprises a first electrode, separate from first electrodes of the other organic photodetectors.

8. The pixel, sensor, or method according to claim 7, wherein each first electrode is coupled to a readout circuit, each readout circuit comprising three transistors formed in the CMOS support.

9. The pixel according to claim 1, wherein said organic photodetectors estimate a distance by time of flight.

10. The pixel according to claim 1, wherein the pixel operates:
in a portion of the infrared spectrum;
in structured light;
in high dynamic range imaging, HDR; and/or
with a background suppression.

11. The image sensor according to claim 2, wherein each pixel further comprises, under the lens, a color filter giving way to electromagnetic waves in a frequency range of the visible spectrum and in the infrared spectrum.

12. The image sensor according to claim 11, wherein the image sensor a color image.

13. The pixel according to claim 1, wherein the pixel comprises only three organic photodetectors including:
the first organic photodetector;
the second organic photodetector; and
a third organic photodetector.

14. The pixel according to claim 13, wherein the third organic photodetector is stacked to the first and second organic photodetectors, and wherein said first and second organic photodetectors are coplanar.

15. The pixel according to claim 13, wherein the first organic photodetector and the second organic photodetector have a rectangular shape and are jointly inscribed within a square.

16. The pixel according to claim 13, wherein each organic photodetector comprises a first electrode, separate from first electrodes of the other organic photodetectors and wherein:
the first organic photodetector is connected to a second electrode;
the second organic photodetector is connected to a third electrode; and
the third organic photodetector is connected to a fourth electrode.

17. The pixel according to claim 13, wherein:
the first organic photodetector and the second organic photodetector comprise a first active layer made of a same first material; and
the third organic photodetector comprises a second active layer made of a second material.

18. The pixel according to claim 17, wherein the first material is different from the second material, said first material being capable of absorbing the electromagnetic waves of part of the infrared spectrum and said second material being capable of absorbing the electromagnetic waves of the visible spectrum.

19. The image sensor according to claim 21, wherein:
the second electrode is common to all the first organic photodetectors of the pixels of the sensor;
the third electrode is common to all the second organic photodetectors of the pixels of the sensor; and
the fourth electrode is common to all the third organic photodetectors of the pixels of the sensor.

20. The image sensor according to claim 2, wherein each pixel comprises only three organic photodetectors including:
the first organic photodetector;
the second organic photodetector; and
a third organic photodetector.

21. The image sensor according to claim 20, wherein each organic photodetector comprises a first electrode, separate from first electrodes of the other organic photodetectors and wherein, for each pixel:
the first organic photodetector is connected to a second electrode;
the second organic photodetector is connected to a third electrode; and
the third organic photodetector is connected to a fourth electrode.

22. A method of manufacturing the image sensor according to claim 2, comprising steps of:
providing a CMOS support;
forming at least two organic photodetectors per pixel; and
forming a same lens vertically in line with the organic photodetectors of each pixel.
